(19) United States
(12) Patent Application Publication
(10) Pub. No.: US 2015/0043753 A1
(43) Pub. Date: Feb. 12, 2015

(54) Systems and Methods for Noise Reduction

(71) Applicant: Marvell World Trade Ltd., St. Michael (BB)

(72) Inventors: Qinwei Gu, Shanghai (CN); Xin Qian, Shanghai (CN)

(21) Appl. No.: 14/446,721

(22) Filed: Jul. 30, 2014

Related U.S. Application Data
(60) Provisional application No. 61/862,620, filed on Aug. 6, 2013.

(51) Int. Cl. H03G 3/20

(52) U.S. Cl. CPC H03G 3/20
USPC 381/107

(57) ABSTRACT

Systems and methods are provided for noise reduction. An input audio signal is received. A target gain corresponding to a target volume level is determined. One or more increments of gain change are determined to reach the target gain. A first non-zero amplitude in the input audio signal is detected. The first non-zero amplitude is not within a predetermined range of zero amplitude. Upon the detection of the first non-zero amplitude in the input audio signal, the one or more increments of gain change are applied at one or more zero-crossing points of the input audio signal. The input audio signal is within the predetermined range of zero amplitude at the one or more zero-crossing points. An output audio signal is generated.

### CROSS-REFERENCE TO RELATED APPLICATIONS

This disclosure claims priority to and benefit from U.S. Provisional Patent Application No. 61/862,620, filed on Aug. 6, 2013, the entirety of which is incorporated herein by reference.

### FIELD

The technology described in this patent document relates generally to audio systems and more particularly to noise reduction in audio systems.

### BACKGROUND

In audio systems, the output of an audio device is often provided to a speaker or an earphone. Volume control in the audio device is usually achieved using an audio gain control circuit. When a sudden gain change is applied by the gain control circuit in the audio device, undesirable artifacts may be produced at the output of the speaker or the earphone. At audio frequencies, such artifacts are often clearly audible, resulting in a pop noise or a soft click.

### SUMMARY

In accordance with the teachings described herein, systems and methods are provided for noise reduction. An input audio signal is received. A target gain corresponding to a target volume level is determined. One or more increments of gain change are determined to reach the target gain. A first non-zero amplitude in the input audio signal is detected. The first non-zero amplitude is not within a predetermined range of zero amplitude. Upon the detection of the first non-zero amplitude in the input audio signal, the one or more increments of gain change are applied at one or more zero-crossing points of the input audio signal. The input audio signal is within the predetermined range of zero amplitude at the one or more zero-crossing points. An output audio signal is generated.

In one embodiment, a device for noise reduction includes: a volume control component configured to determine a target gain corresponding to a target volume level and determine one or more increments of gain change to reach the target gain; a detection component configured to detect a first non-zero amplitude in the input audio signal, the first non-zero amplitude being not within a predetermined range of zero amplitude; and a gain circuit configured to, upon the detection of the first non-zero amplitude in the input audio signal, apply the one or more increments of gain change at one or more zero-crossing points and generate an output audio signal, the input audio signal being within a predetermined range of zero amplitude at the one or more zero-crossing points.

In another embodiment, a system for noise reduction includes: one or more data processors configured to: determine a target gain corresponding to a target volume level for an input audio signal, determine one or more increments of gain change to reach the target gain, detect a first non-zero amplitude in the input audio signal, the first non-zero amplitude being not within a predetermined range of zero amplitude, and upon the detection of the first non-zero amplitude in the input audio signal, apply the one or more increments of gain change at one or more zero-crossing points to generate an output audio signal. The input audio signal is within the predetermined range of zero amplitude at the one or more zero-crossing points. The system further includes one or more computer-readable storage media configured to store the target gain and the one or more increments of gain change.

### BRIEF DESCRIPTION OF THE DRAWINGS

FIG. 1 depicts an example timing diagram of an input audio signal.

FIG. 2 depicts another example timing diagram of an input audio signal.

FIG. 3 depicts another example timing diagram of an input audio signal.

FIG. 4 depicts an example diagram showing a device for noise reduction.

FIG. 5 depicts another example diagram showing a device for noise reduction.

FIG. 6 depicts yet another example diagram showing a device for noise reduction.

FIG. 7 depicts an example flow chart for noise reduction.

### DETAILED DESCRIPTION

Audio artifacts caused by sudden gain change for volume control may be reduced by volume ramping in combination with zero crossing detection. Volume ramping creates small steps (e.g., increments) of gain change to avoid any sudden (e.g., a large step) gain change. In addition, the small steps (e.g., increments) of gain change are synchronized with zero-crossing points of an input audio signal. As the input audio signal has approximately zero amplitude (e.g., within a predetermined range of zero amplitude) at the zero-crossing points, ideally the audio artifacts caused by a small step of gain change should be negligible.

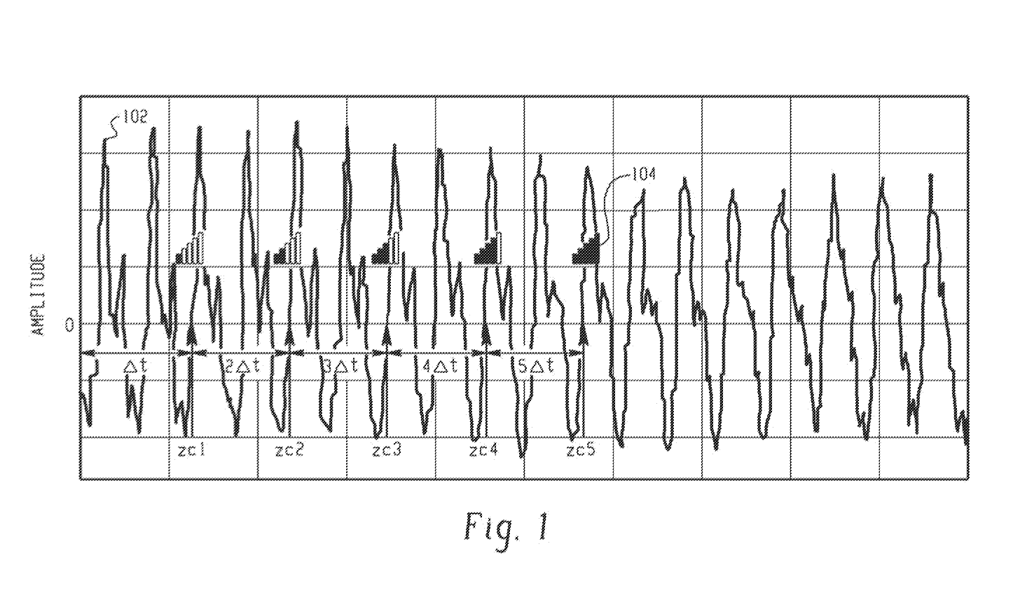

FIG. 1 depicts an example timing diagram of an input audio signal. As shown in FIG. 1, increments of gain change are applied at live zero-crossing points (e.g., zc1, zc2, zc3, zc4 and zc5) to reach a target gain. Specifically, the zero-crossing points (e.g., zc1, zc2, zc3, zc4 and zc5) are detected in the input audio signal 102, where the zero-crossing points are separated by an approximately same time interval (e.g., Δt). At each zero-crossing point, an increment of gain change is applied, until a target gain 104 is reached at the zero-crossing point zc5.

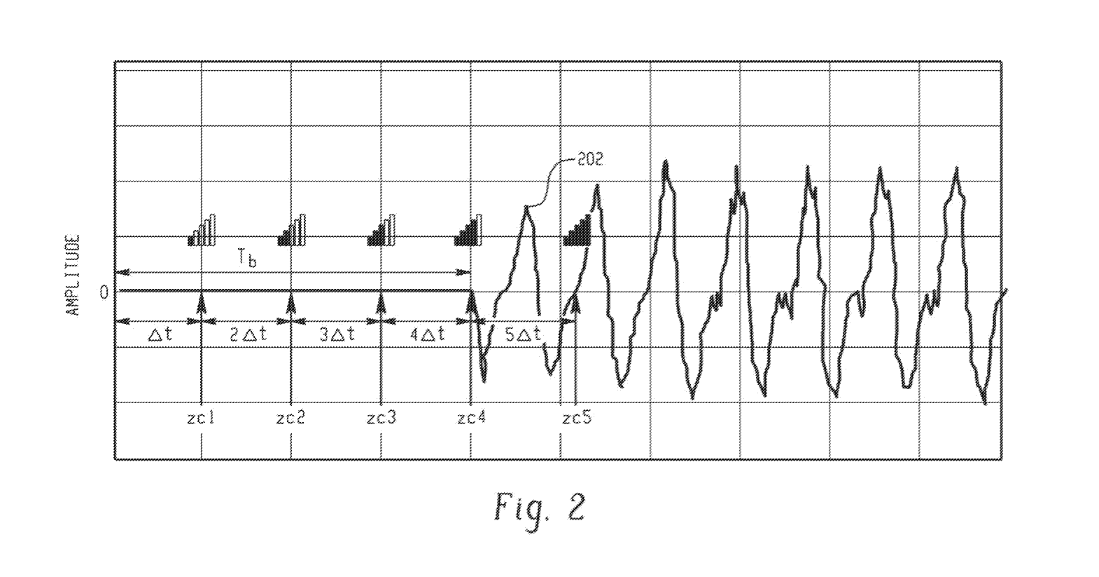

However, for certain input audio signals, volume ramping in combination with zero crossing detection may not effectively reduce audio artifacts. As shown in FIG. 2., before real audio data in an input audio signal 202 arrives, the input audio signal 202 remains at approximately zero amplitude (e.g., full zero data) during a time period T_{b}. If increments of gain change are applied during the time period T_{b}, e.g., at the zero-crossing points zc1, zc2, zc3, and zc4, the accumulated gain change is negligible. Then, when the real data in the input audio signal 202 arrives, the gain change applied at the zero-crossing points zc5 corresponds in effect to a large step in order to reach the target gain, which may cause undesirable noise.

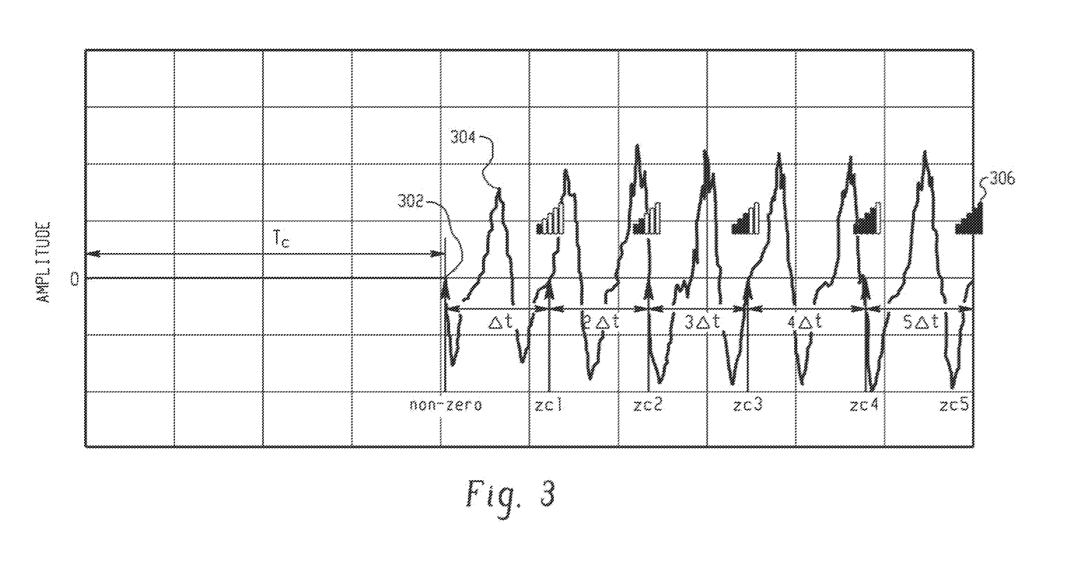

FIG. 3 depicts another example timing diagram of an input audio signal. As shown in FIG. 3, a first non-zero amplitude 302 is detected in an input audio signal 304, and upon the detection of the first non-zero amplitude 302, volume ramping and zero-crossing detection begin to be applied for volume control.

Specifically, before real audio data in the input audio signal 304 arrives, the input audio signal 304 remains at approximately zero amplitude (e.g., within a predetermined range of zero amplitude) during a time period T. No gain change is applied during the time period T. Amplitude detection is performed to detect the first non-zero amplitude 302 (e.g., not within the predetermined range of zero amplitude). For example, the input audio signal 304 is sampled at a particular frequency for non-zero amplitude detection.

Once the first non-zero amplitude 302 is detected, increments of gain change are applied at various zero-crossing points (e.g., zc1, zc2, zc3, zc4, and zc5) of the input audio signal 304. The zero-crossing points zc1, zc2, zc3, zc4, and zc5 of the input audio signal 304 are detected one by one, and an increment of gain change is applied upon the detection of each zero-crossing point until a target gain 306 is reached. For example, the zero-crossing points are detected by sampling the input audio signal 304 at a predetermined frequency which may be different from the frequency for detecting the first non-zero amplitude 302.

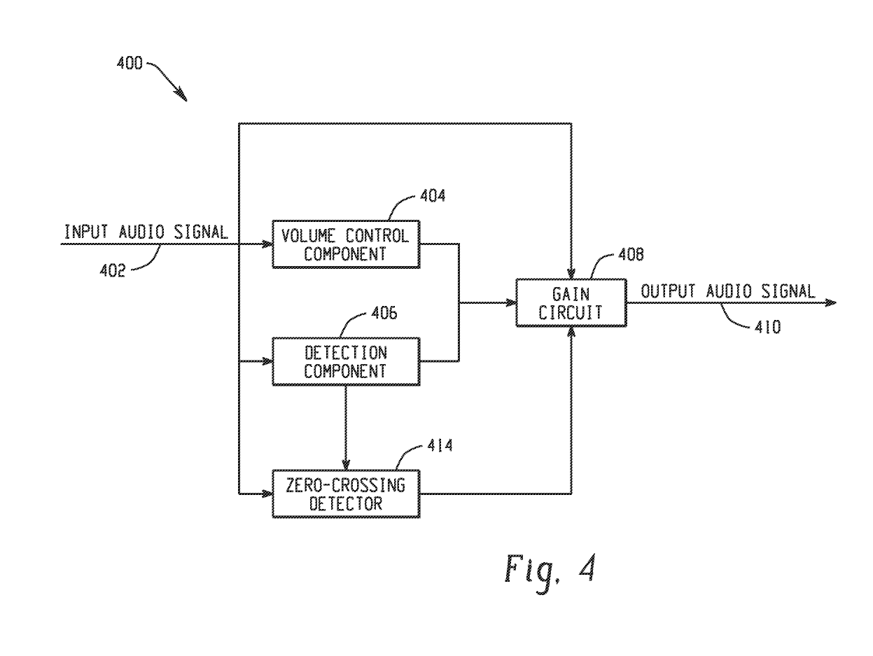

FIG. 4 depicts an example diagram showing a device for noise reduction. As shown in FIG. 4, the device 400 performs volume control by applying volume ramping at zero-crossing points of an input audio signal 402 after a first non-zero amplitude of the input audio signal 402 is detected.

Specifically, a volume control component 404 determines a target gain corresponding to a target volume level (e.g., determined by user input) and determines one or more increments of gain change to reach the target gain. A detection component 406 detects the first non-zero amplitude (e.g., not within a predetermined range of zero amplitude) in the input audio signal 402. A zero-crossing detector 414 detects, upon the detection of the first non-zero amplitude, one or more zero-crossing points at which the input audio signal 402 is within the predetermined range of zero amplitude. A gain circuit 408 applies the one or more increments of gain change at the detected zero-crossing points and generates an output audio signal 410. For example, a ratio related to the output audio signal 410 and the input audio signal 402 is approximately equal to the target gain.

In some embodiments, the first non-zero amplitude is preceded by a time period during which the input audio signal 402 remains within the predetermined range of zero amplitude. The gain circuit 408 applies no gain change during the time period.

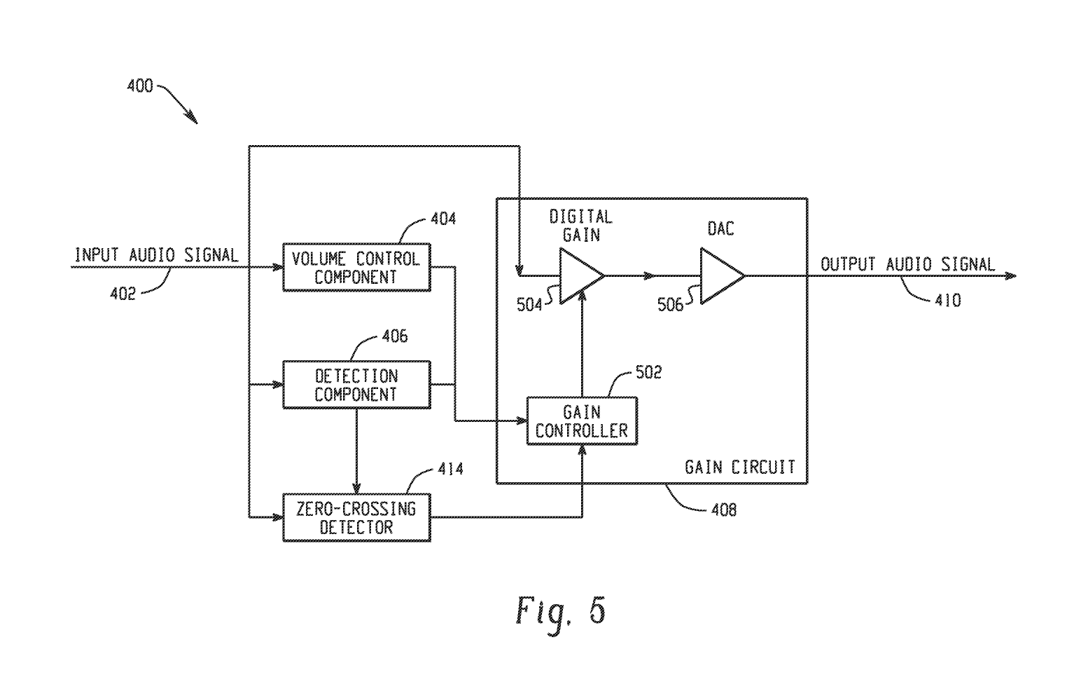

FIG. 5 depicts another example diagram showing a device for noise reduction. As shown in FIG. 5, the gain circuit 408 includes a gain controller 502, a digital gain component 504, and a digital-analog converter (DAC) 506. The gain controller 502 controls the digital gain component 504 to apply increments of gain change at zero-crossing points in the input audio signal 402. The output of the digital gain component 504 is converted to the output audio signal 410 by the DAC 506.

Specifically, the gain controller 502 controls the digital gain component 504 so that the digital gain component 504 does not apply any gain change until the first non-zero amplitude in the input audio signal 402 is detected by the detection component 406. In addition, after the first non-zero amplitude in the input audio signal 402 is detected, the gain controller 502 controls the digital gain component 504 to apply the increments of gain change determined by the volume control component 404 at the detected zero-crossing points detected by the zero-crossing detector 414.

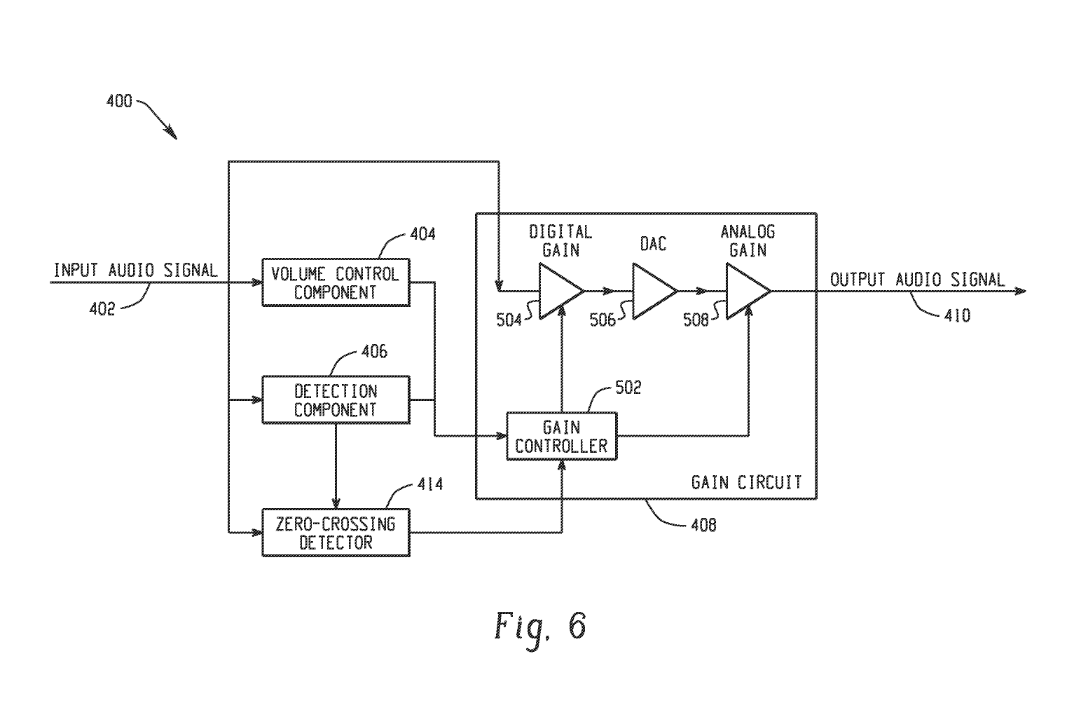

FIG. 6 depicts yet another example diagram showing a device for noise reduction. As shown in FIG. 6, the gain circuit 408 further includes an analog gain component 508. The gain controller 502 controls the analog gain component 508 to amplify the output of the DAC 506 to generate the output audio signal 410. For example, the analog gain component 508 includes an amplifier. The gain controller 502 may control the analog gain component 508 as well as the digital gain component 504 to reach the target gain.

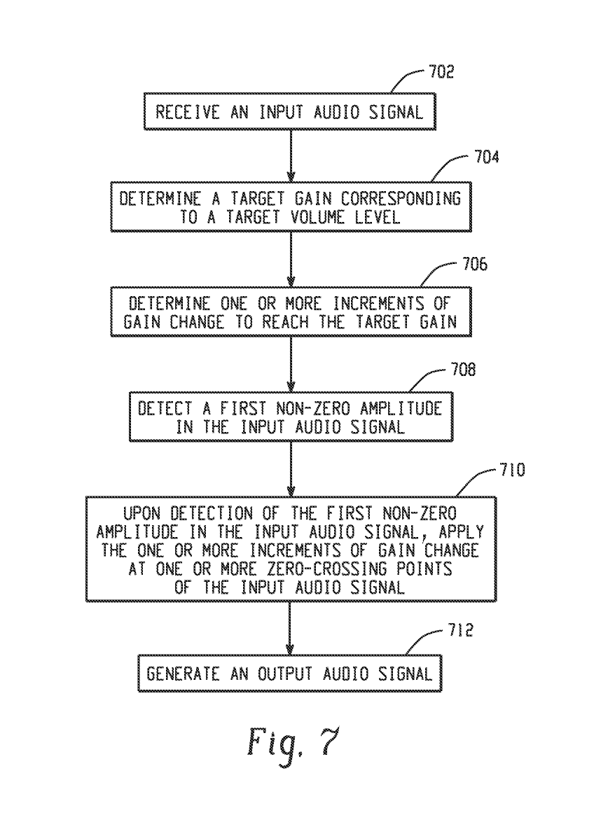

FIG. 7 depicts an example flow chart for noise reduction. At 702, an input audio signal is received. At 704, a target gain corresponding to a target volume level is determined. At 706, one or more increments of gain change are determined to reach the target gain. At 708, a first non-zero amplitude in the input audio signal is detected. The first non-zero amplitude is not within a predetermined range of zero amplitude. At 710, upon the detection of the first non-zero amplitude in the input audio signal, the one or more increments of gain change are applied at one or more zero-crossing points of the input audio signal. The input audio signal is within the predetermined range of zero amplitude at the one or more zero-crossing points. At 712, an output audio signal is generated.

This written description uses examples to disclose the invention, include the best mode, and also to enable a person skilled in the art to make and use the invention. The patentable scope of the invention may include other examples that occur to those skilled in the art. Other implementations may also be used, however, such as firmware or appropriately designed hardware configured to carry out the methods and systems described herein. For example, the systems and methods described herein may be implemented in an independent processing engine, as a co-processor, or as a hardware accelerator. In yet another example, the systems and methods described herein may be provided on many different types of computer-readable media including computer storage mechanisms (e.g., CD-ROM, diskette, RAM, flash memory, computer's hard drive, etc.) that contain instructions (e.g., software) fir use in execution by one or more processors to perform the methods' operations and implement the systems described herein.

What is claimed is:

1. A method for noise reduction, the method comprising:
receiving an input audio signal;
determining a target gain corresponding to a target volume level;
determining one or more increments of gain change to reach the target gain;
detecting a first non-zero amplitude in the input audio signal, the first non-zero amplitude being not within a predetermined range of zero amplitude;
upon the detection of the first non-zero amplitude in the input audio signal, applying the one or more increments of gain change at one or more zero-crossing points of the input audio signal, wherein the input audio signal is within the predetermined range of zero amplitude at the one or more zero-crossing points; and
generating an output audio signal.

2. The method of claim 1, wherein the first non-zero amplitude is preceded by a time period during which the input audio signal remains within the predetermined range of zero amplitude.

3. The method of claim 2, wherein no gain change is applied to the input audio signal during the time period.

4. The method of claim 1, further comprising:
detecting the one or more zero-crossing points in response to the first non-zero amplitude being detected.

5. The method of claim 1, wherein:
the one or more increments of gain change include a first increment and a second increment;
the applying the one or more increments of gain changes at one or more zero-crossing points of the input audio signal includes:
applying the first increment of gain change and the second increment of gain change at a first zero-crossing point and a second zero-crossing point respectively.

6. The method of claim 1, wherein a ratio related to the output audio signal and the input audio signal corresponds to the target gain.

7. The method of claim 1, wherein:
the one or more zero-crossing points are detected by sampling the input audio signal at a first frequency; and
the first non-zero amplitude is detected by sampling the input audio signal at a second frequency, the second frequency being different from the first frequency.

8. A device for noise reduction comprising:
a volume control component configured to determine a target gain corresponding to a target volume level and determine one or more increments of gain change to reach the target gain;
a detection component configured to detect a first non-zero amplitude in the input audio signal, the first non-zero amplitude being not within a predetermined range of zero amplitude; and
a gain circuit configured to, upon the detection of the first non-zero amplitude in the input audio signal, apply the one or more increments of gain change at one or more zero-crossing points and generate an output audio signal, the input audio signal being within a predetermined range of zero amplitude at the one or more zero-crossing points.

9. The device of claim 8, wherein the first non-zero amplitude is preceded by a time period during which the input audio signal remains within the predetermined range of zero amplitude.

10. The device of claim 9, wherein the gain circuit is further configured to apply no gain change during the time period.

11. The device of claim 8, wherein:
the one or more increments of gain changes includes a first increment of gain change and a second increment of gain change; and
the gain circuit is further configured to apply the first increment of gain change and the second increment of gain change at a first zero-crossing point and a second zero-crossing point respectively.

12. The device of claim 8, wherein a ratio related to the output audio signal and the input audio signal corresponds to the target gain.

13. The device of claim 8, further comprising:
a zero-crossing detector configured to detect the one or more zero-crossing points in response to the first non-zero amplitude being detected.

14. The device of claim 13, wherein:
the zero-crossing detector is further configured to sample the input audio signal at a first frequency to detect the one or more zero-crossing points; and
the detection component is further configured to sample the input audio signal at a second frequency to detect the first non-zero amplitude, the second frequency being different from the first frequency.

15. A system for noise reduction comprising:
one or more data processors configured to:
determine a target gain corresponding to a target volume level for an input audio signal;
determine one or more increments of gain change to reach the target gain;
detect a first non-zero amplitude in the input audio signal, the first non-zero amplitude being not within a predetermined range of zero amplitude; and
upon the detection of the first non-zero amplitude in the input audio signal, apply the one or more increments of gain change at one or more zero-crossing points to generate an output audio signal, wherein the input audio signal is within the predetermined range of zero amplitude at the one or more zero-crossing points; and
one or more computer-readable storage media configured to store the target gain and the one or more increments of gain change.

16. The system of claim 15, wherein the first non-zero amplitude is preceded by a time period during which the input audio signal remains within the predetermined range of zero amplitude.

17. The system of claim 16, wherein no gain change is applied to the input audio signal during the time period.

18. The system of claim 15, wherein:
the one or more increments of gain change include a first increment and a second increment;
the applying the one or more increments of gain changes at one or more zero-crossing points of the input audio signal includes:
applying the first increment of gain change and the second increment of gain change at a first zero-crossing point and a second zero-crossing point respectively.

19. The system of claim 15, wherein a ratio related to the output audio signal and the input audio signal corresponds to the target gain.

20. The system of claim 15, wherein:
the one or more zero-crossing points are detected by sampling the input audio signal at a first frequency; and
the first non-zero amplitude is detected by sampling the input audio signal at a second frequency, the second frequency being different from the first frequency.
